(19) United States
(12) Patent Application Publication
(10) Pub. No.: US 2017/0141131 A1
(43) Pub. Date: May 18, 2017

(54) SEMICONDUCTOR DEVICE

(71) Applicant: Kabushiki Kaisha Toshiba, Minato-ku (JP)

(72) Inventors: Shintaro NAKANO, Kawasaki (JP); Kentaro MIURA, Kawasaki (JP); Yuya MAEDA, Kawasaki (JP)

(73) Assignee: Kabushiki Kaisha Toshiba, Minato-ku (JP)

(21) Appl. No.: 15/418,002

(22) Filed: Jan. 27, 2017

Related U.S. Application Data
(63) Continuation of application No. PCT/JP2015/072715, filed on Aug. 10, 2015.

(30) Foreign Application Priority Data
Mar. 3, 2015 (JP) 2015-041513

(51) Int. Cl. H01L 27/12

(52) U.S. Cl. CPC H01L 27/1225

(57) ABSTRACT

According to one embodiment, a semiconductor device includes a substrate, a semiconductor layer, a source electrode, a drain electrode, first insulating portion and second insulating portions. The semiconductor layer includes an oxide and is separated from the substrate in a first direction. The source electrode is electrically connected to the semiconductor layer. The drain electrode is electrically connected to the semiconductor layer and is arranged with the source electrode in a second direction crossing the first direction. The first insulating portion is provided between the substrate and the semiconductor layer. The semiconductor layer is provided between the first and second insulating portions. The first insulating portion includes a first silicon nitride layer, and a first aluminum oxide layer stacked with the first silicon nitride layer. The second insulating portion includes a second aluminum oxide layer, and a second silicon nitride layer stacked with the second aluminum oxide layer.

### CROSS-REFERENCE TO RELATED APPLICATIONS

This is a continuation application of International Application PCT/JP2015/072715, filed on Aug. 10, 2015. This application also claims priority to Japanese Application No. 2015-041513, filed on Mar. 3, 2015. The entire contents of each are incorporated herein by reference.

### FIELD

Embodiments of the invention relate generally to a semiconductor device.

### BACKGROUND

A TFT (Thin Film Transistor) that uses an oxide semiconductor is used widely in liquid crystal display devices, organic electroluminescence (EL) display devices, etc. In particular, a TFT that uses an amorphous oxide semiconductor including indium (In), gallium (Ga), and zinc (Zn) (called In—Ga—Zn—O (IGZO)) is drawing attention. If hydrogen penetrates excessively into the oxide semiconductor, the resistance of the oxide semiconductor may be reduced; and the electrical characteristics of the oxide semiconductor may fluctuate. Therefore, it is desirable to stabilize the electrical characteristics of the semiconductor device using the oxide semiconductor.

### BRIEF DESCRIPTION OF THE DRAWINGS

FIG. 1 is a schematic cross-sectional view illustrating a semiconductor device according to a first embodiment;

FIG. 2 is a schematic plan view illustrating the semiconductor device according to the first embodiment;

FIG. 3 is a graph illustrating evaluation results of the hydrogen barrier property;

FIG. 4 is a figure illustrating the evaluation results of the hydrogen barrier property;

FIG. 5 is a graph illustrating the evaluation results of the hydrogen barrier property;

FIG. 6 is a photograph illustrating the cross section of the semiconductor device according to the first embodiment;

FIG. 7A and FIG. 7B are figures illustrating the composition ratios of the first layer and the second layer;

FIG. 8A and FIG. 8B, are schematic cross-sectional views in order of the processes, illustrating a method for manufacturing the semiconductor device according to the first embodiment;

FIG. 9A and FIG. 9B, are schematic cross-sectional views in order of the processes, illustrating the method for manufacturing the semiconductor device according to the first embodiment;

FIG. 10A and FIG. 10B, are schematic cross-sectional views in order of the processes, illustrating the method for manufacturing the semiconductor device according to the first embodiment;

FIG. 11 is a schematic cross-sectional view in order of the processes, illustrating the method for manufacturing the semiconductor device according to the first embodiment;

FIG. 12 is a schematic cross-sectional view illustrating a semiconductor device according to a second embodiment;

FIG. 13A and FIG. 13B are schematic cross-sectional views in order of the processes, illustrating a method for manufacturing the semiconductor device according to the second embodiment;

FIG. 14A and FIG. 14B are schematic cross-sectional views in order of the processes, illustrating the method for manufacturing the semiconductor device according to the second embodiment;

FIG. 15A and FIG. 15B are schematic cross-sectional views in order of the processes, illustrating the method for manufacturing the semiconductor device according to the second embodiment;

FIG. 16A and FIG. 16B are schematic cross-sectional views in order of the processes, illustrating the method for manufacturing the semiconductor device according to the second embodiment;

FIG. 17A and FIG. 17B are schematic cross-sectional views in order of the processes, illustrating the method for manufacturing the semiconductor device according to the second embodiment; and

FIG. 18 is a schematic cross-sectional view in order of the processes, illustrating the method for manufacturing the semiconductor device according to the second embodiment.

### DETAILED DESCRIPTION

According to one embodiment, a semiconductor device includes a substrate, a semiconductor layer, a source electrode, a drain electrode, a first insulating portion, and a second insulating portion. The semiconductor layer includes an oxide and is separated from the substrate in a first direction. The source electrode is electrically connected to the semiconductor layer. The drain electrode is electrically connected to the semiconductor layer and is arranged with the source electrode in a second direction crossing the first direction. The first insulating portion is provided between the substrate and the semiconductor layer. The semiconductor layer is provided between the first insulating portion and the second insulating portion. The first insulating portion includes a first silicon nitride layer, and a first aluminum oxide layer stacked with the first silicon nitride layer. The second insulating portion includes a second aluminum oxide layer, and a second silicon nitride layer stacked with the second aluminum oxide layer.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### First Embodiment

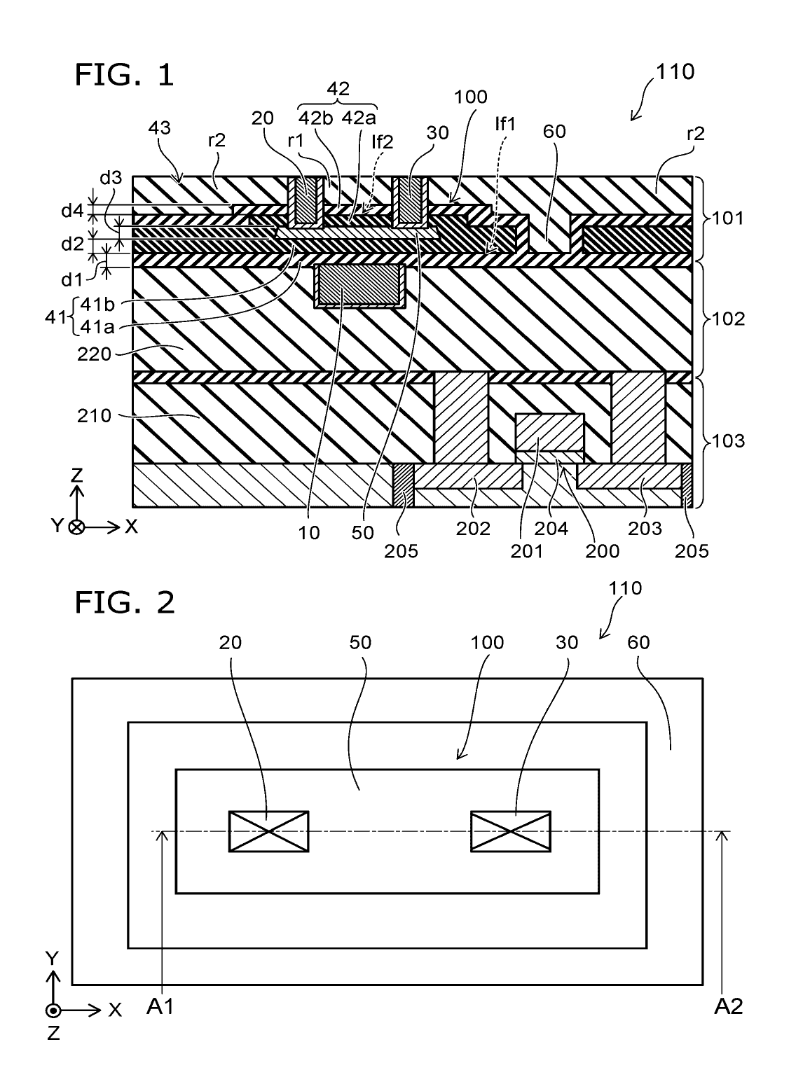

FIG. 1 is a schematic cross-sectional view illustrating a semiconductor device according to a first embodiment.

FIG. 2 is a schematic plan view illustrating the semiconductor device according to the first embodiment.

FIG. 1 shows an A1-A2 cross section of FIG. 2.

The semiconductor device 110 according to the embodiment includes a first interconnect layer 101, a second interconnect layer 102, and a substrate 103. The second interconnect layer 102 is provided between the first interconnect layer 101 and the substrate 103.

A semiconductor element 200 and an insulating layer 210 are provided in the substrate 103. The semiconductor element 200 is, for example, a MOSFET (Metal Oxide Semiconductor Field Effect Transistor). The semiconductor element 200 includes a gate electrode 201, a source electrode 202, a drain electrode 203, and a gate insulating layer 204. The element region where the semiconductor element 200 is provided is separated from other element regions by an element separation layer 205. The insulating layer 210 includes, for example, silicon oxide (SiOₓ).

The second interconnect layer 102 is provided on the substrate 103. A gate electrode 10 and an insulating layer 220 are provided in the second interconnect layer 102. The insulating layer 220 includes, for example, silicon oxide.

The first interconnect layer 101 is provided on the second interconnect layer 102. A thin film transistor 100 is provided in the first interconnect layer 101. The thin film transistor 100 is provided on the substrate 103 with the second interconnect layer 102 interposed. The thin film transistor 100 includes the gate electrode 10, a source electrode 20, a drain electrode 30, a first insulating portion 41, a second insulating portion 42, and a semiconductor layer 50. A trench portion 60 is provided around the thin film transistor 100. For example, the semiconductor element 200 is disposed at a position overlapping the trench portion 60 in a Z-axis direction. Herein, “overlapping” refers to the state in which at least a portion overlaps when viewed from the Z-axis direction when projected onto a plane orthogonal to the Z-axis direction. The semiconductor element 200 may be disposed at a position overlapping the thin film transistor 100; and the position of the semiconductor element 200 is not particularly limited.

In the example, a direction (the stacking direction) from the gate electrode 10 toward the semiconductor layer 50 is taken as the Z-axis direction. One direction perpendicular to the Z-axis direction is taken as an X-axis direction. The X-axis direction is, for example, the direction from the source electrode 20 toward the drain electrode 30. One direction perpendicular to the Z-axis direction and the X-axis direction is taken as a Y-axis direction.

The semiconductor layer 50 includes an oxide of at least one of In, Ga, or Zn. The semiconductor layer 50 includes, for example, InGaZnO (IGZO). The semiconductor layer 50 may include N and at least one of In, Ga, or Zn. The semiconductor layer 50 may include InGaZnO:N, InZnO, InGaO, InSnZnO, InSnGaZnO, or InSnO.

The gate electrode 10 includes, for example, one of W, Mo, Ta, TaN, Ti, TiN, Al, AlNd, Cu, ITO, or IZO. The gate electrode 10 may include an alloy of these materials, or a stacked structure of films of these materials.

The source electrode 20 and the drain electrode 30 include, for example, one of Ti, Mo, Al, Cu, Ta, W, TiN, TaN, MoN, ITO, IZO, InGaZn, or InGaZnO:N. The source electrode 20 and the drain electrode 30 may include an alloy of these materials or a stacked structure of films of these materials.

The first insulating portion 41 is provided between the semiconductor layer 50 and the gate electrode 10. The first insulating portion 41 functions as a gate insulating layer. A stacked structure of silicon nitride (SiNₓ) and aluminum oxide (AlOₓ) is used as the first insulating portion 41.

The second insulating portion 42 is provided on the semiconductor layer 50. In other words, the semiconductor layer 50 is provided between the first insulating portion 41 and the second insulating portion 42. The periphery of the semiconductor layer 50 is covered with the first insulating portion 41 and the second insulating portion 42. A stacked structure of silicon nitride and aluminum oxide is used as the second insulating portion 42.

In the embodiment, the semiconductor layer 50 is provided to be separated from the substrate 103 in a first direction. The first direction is, for example, the Z-axis direction. The source electrode 20 is electrically connected to the semiconductor layer 50. For example, the source electrode 20 contacts the semiconductor layer 50. The drain electrode 30 is electrically connected to the semiconductor layer 50 and is arranged with the source electrode 20 in a second direction crossing the Z-axis direction. The second direction is, for example, the X-axis direction. For example, the drain electrode 30 contacts the semiconductor layer 50.

The first insulating portion 41 is provided between the substrate 103 and the semiconductor layer 50. The semiconductor layer 50 is provided between the first insulating portion 41 and the second insulating portion 42. The first insulating portion 41 includes a first silicon nitride layer 41a and a first aluminum oxide layer 41b. The first aluminum oxide layer 41b is stacked with the first silicon nitride layer 41a. The second insulating portion 42 includes a second aluminum oxide layer 42a and a second silicon nitride layer 42b. The second silicon nitride layer 42b is stacked with the second aluminum oxide layer 42a.

In the example, the first aluminum oxide layer 41b is provided between the first silicon nitride layer 41a and the semiconductor layer 50. The second aluminum oxide layer 42a is provided between the second silicon nitride layer 42b and the semiconductor layer 50.

A thickness d1 of the first silicon nitride layer 41a is not less than 10 nanometers (nm) and not more than 100 nm. A thickness d2 of the first aluminum oxide layer 41b is not less than 5 nm and not more than 100 nm. A thickness d3 of the second aluminum oxide layer 42a is not less than 5 nm and not more than 100 nm. A thickness d4 of the second silicon nitride layer 42b is not less than 10 nm and not more than 100 nm.

The semiconductor device 110 further includes a third insulating portion 43. The third insulating portion 43 is provided on the second insulating portion 42. The second insulating portion 42 is provided between the semiconductor layer 50 and the third insulating portion 43. The third insulating portion 43 includes one of silicon oxide (SiOₓ) or silicon oxynitride (SiONₓ).

The semiconductor device 110 of the embodiment includes the thin film transistor 100 having a bottom-gate structure in which the gate electrode 10 is disposed on the lower side of the semiconductor layer 50.

The first insulating portion 41 includes a first layer If1. The first layer If1 is positioned between the first silicon nitride layer 41a and the first aluminum oxide layer 41b. The second insulating portion 42 includes a second layer If2. The second layer If2 is positioned between the second aluminum oxide layer 42a and the second silicon nitride layer 42b.

The first layer If1 is illustrated as a layer in which silicon nitride and aluminum oxide coexist between the first silicon nitride layer 41a and the first aluminum oxide layer 41b. That is, the first layer If1 contains nitrogen, oxygen, aluminum, and silicon. The second layer If2 is illustrated as a layer in which aluminum oxide and silicon nitride coexist between the second aluminum oxide layer 42a and the second silicon nitride layer 42b. That is, the second layer If2 contains nitrogen, oxygen, aluminum, and silicon.

Here, if hydrogen penetrates excessively into the oxide semiconductor such as IGZO, etc., the resistance of the oxide semiconductor may be reduced; and the electrical characteristics of the oxide semiconductor may fluctuate. In other words, the hydrogen that penetrates the oxide semiconductor reacts with the oxygen bonded to the metal atoms to form water; and an oxygen deficiency occurs in the lattice where the oxygen has desorbed (or the portions where the oxygen has desorbed). Then, by the hydrogen entering where the oxygen deficiency has occurred, electrons which are carriers are generated; and a parasitic channel may be formed. Thereby, it is considered that the resistance of the oxide semiconductor decreases; and the electrical characteristics undesirably fluctuate.

Conversely, the inventors discovered that a stacked structure of silicon nitride and aluminum oxide is effective as a hydrogen barrier layer to suppress the penetration of the hydrogen into the oxide semiconductor.

According to the embodiment, the first insulating portion and the second insulating portion 42 that cover the semiconductor layer 50 are provided. The first insulating portion 41 is a stacked structure of the first silicon nitride layer 41a and the first aluminum oxide layer 41b. The second insulating portion 42 is a stacked structure of the second aluminum oxide layer 42a and the second silicon nitride layer 42b. The first insulating portion 41 and the second insulating portion 42 function as a hydrogen barrier layer; and the penetration of the hydrogen into the semiconductor layer 50 is suppressed. In other words, it is considered that the hydrogen is trapped by the first layer If1 positioned between the first silicon nitride layer 41a and the first aluminum oxide layer 41b and by the second layer If2 positioned between the second aluminum oxide layer 42a and the second silicon nitride layer 42b; and the penetration of the hydrogen into the semiconductor layer 50 is suppressed.

Thereby, the resistance reduction of the semiconductor layer 50 is suppressed; and the fluctuation of the electrical characteristics can be suppressed.

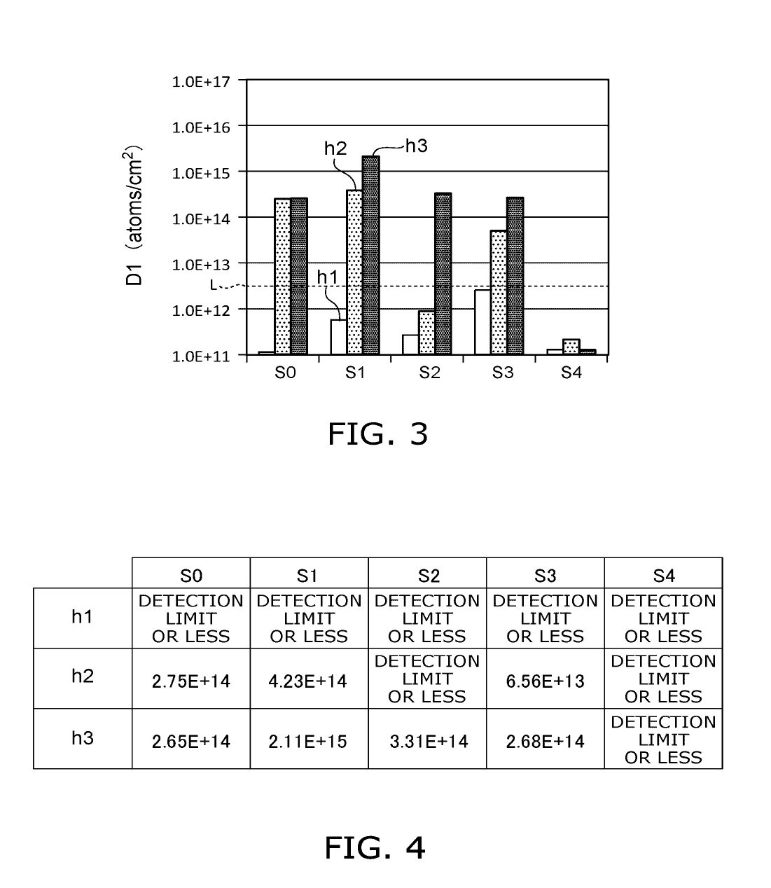

FIG. 3 is a graph illustrating evaluation results of the hydrogen barrier property.

In the figure, D1 of the vertical axis shows the detection amount (atoms/cm²) of deuterium atoms D. S0 to S4 of the horizontal axis show the samples. Detection amounts h1 to h3 are shown as integrals of the number of deuterium atoms per unit surface area for each of samples S0 to S4. Samples S0 to S4 each include a silicon (Si) layer, a silicon oxide layer provided on the silicon layer, an oxide semiconductor (IGZO) layer provided on the silicon oxide layer, and an insulating layer provided on the oxide semiconductor layer. The thickness of the silicon oxide layer is 200 nanometers (nm). The thickness of the oxide semiconductor layer is 200 nm.

Sample S0 has a structure in which the insulating layer is not provided. The insulating layer has a silicon oxide (SiOₓ) single-layer structure in sample S1. The insulating layer has an aluminum oxide (AlOₓ) single-layer structure in sample S2. The insulating layer has a silicon nitride (SiNₓ) single-layer structure in sample S3. The insulating layer has a stacked structure of silicon nitride (SiNₓ)/aluminum oxide (AlOₓ)/silicon oxide (SiOₓ) in sample S4.

Samples S0 to S4 were placed in a mixed atmosphere of nitrogen (N₂) and deuterium (D₂: 2%); the detection amount h1 inside the oxide semiconductor layer before annealing was measured; the detection amount h2 inside the oxide semiconductor layer after annealing at 350° C. was measured; and the detection amount h3 inside the oxide semiconductor layer after annealing at 420° C. was measured.

FIG. 4 is a figure illustrating the evaluation results of the hydrogen barrier property.

Specific numerical examples according to the graph of FIG. 3 are shown in FIG. 4. In the case of sample S4 according to the embodiment, the detection amounts h1 to h all are the detection limit or less. The detection limit L is, for example, 4×10¹² (atom/cm²). The dotted line of FIG. 3 shows the detection limit L. As a reference, in the case of sample S1, h1 is the detection limit or less; h2 is 4.23×10¹⁴ (atoms/cm²); and h3 is 2.11×10¹⁵ (atoms/cm²). In the case of sample S2, h1 and h2 are the detection limit or less; and h3 is 3.31×10¹⁴ (atoms/cm²). In the case of sample S3, h1 is the detection limit or less; h2 is 6.56×10¹³ (atoms/cm²); and h3 is 2.68×10¹⁴ (atoms/cm²).

The insulating layers of samples S1 to S3 have, in order, a silicon oxide single-layer structure, an aluminum oxide single-layer structure, and a silicon nitride single-layer structure. Conversely, the insulating layer of sample S4 has a stacked structure of silicon nitride/aluminum oxide/silicon oxide. It can be seen that the detection amounts h1 to h3 are low for sample S4 compared to samples S1 to S3. That is, in the single-layer structures of samples S1 to S3, the deuterium undesirably permeates and penetrates the oxide semiconductor layer. Conversely, it is considered that the permeation of the deuterium is suppressed by the stacked structure of sample S4; and the penetration into the oxide semiconductor layer is suppressed. Thereby, it can be said that the stacked structure of sample S4 has a high hydrogen barrier property.

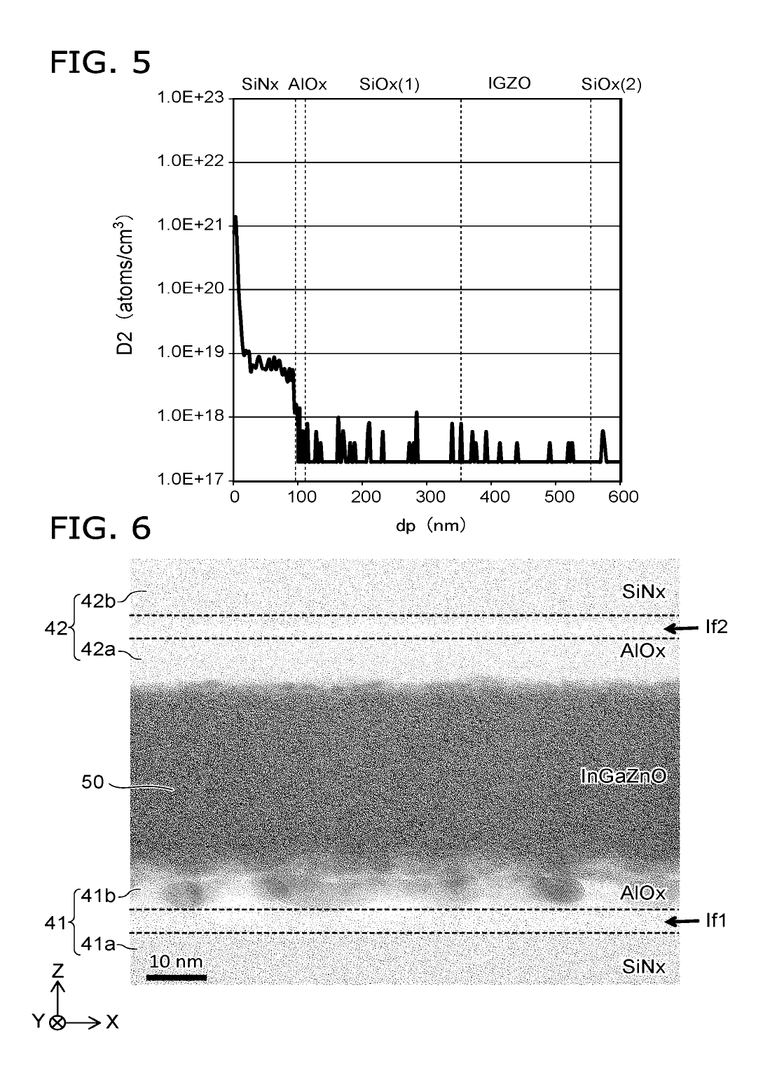

FIG. 5 is a graph illustrating the evaluation results of the hydrogen barrier property.

In the figure, D2 of the vertical axis shows the concentration (atoms/cm³) of the deuterium atoms D. dp of the horizontal axis shows the depth (nm) in the stacking direction of the sample. The sample of the example has a stacked structure of a silicon nitride layer, an aluminum oxide layer, a silicon oxide (1) layer, an oxide semiconductor layer, and a silicon oxide (2) layer. The depth dp (nm) of the horizontal axis is shown in the range of 0 to 600 (nm) in the direction from the silicon nitride layer toward the silicon oxide (2) layer. In the example, the thickness of the silicon nitride layer is 100 nm. The thickness of the aluminum oxide layer is 10 nm. The thickness of the silicon oxide (1) layer is 250 nm. The thickness of the oxide semiconductor layer is 200 nm.

FIG. 5 shows the deuterium concentrations of the layers after placing the sample recited above in a mixed atmosphere of nitrogen (N₂) and deuterium (D₂) and annealing for 1 hour at 420° C. The layers are the silicon nitride layer, the aluminum oxide layer, the silicon oxide (1) layer, the oxide semiconductor layer, and the silicon oxide (2) layer. According to FIG. 5, it can be seen that the deuterium concentration abruptly decreases at the interface vicinity between the silicon nitride layer and the aluminum oxide layer. It is considered that deuterium is trapped at the interface between the silicon nitride layer and the aluminum oxide layer. The penetration of the deuterium into the oxide semiconductor layer is suppressed by the deuterium trapped at the interface between the silicon nitride layer and the aluminum oxide layer.

FIG. 6 is a photograph illustrating the cross section of the semiconductor device according to the first embodiment.

As shown in FIG. 6, the semiconductor layer 50 is provided on the first insulating portion 41. The first insulating portion 41 includes the first silicon nitride layer 41a, and the first aluminum oxide layer 41b stacked with the first silicon nitride layer 41a. The second insulating portion 42 is provided on the semiconductor layer 50. The second insulating portion 42 includes the second aluminum oxide layer 42a, and the second silicon nitride layer 42b stacked with the second aluminum oxide layer 42a.

The first insulating portion 41 includes the first layer If1. The first layer If1 is positioned between the first silicon nitride layer 41a and the first aluminum oxide layer 41b. The first layer If1 contains nitrogen, oxygen, aluminum, and silicon. The second insulating portion 42 includes the second layer If2. The second layer If2 is positioned between the second aluminum oxide layer 42a and the second silicon nitride layer 42b. The second layer If2 contains nitrogen, oxygen, aluminum, and silicon.

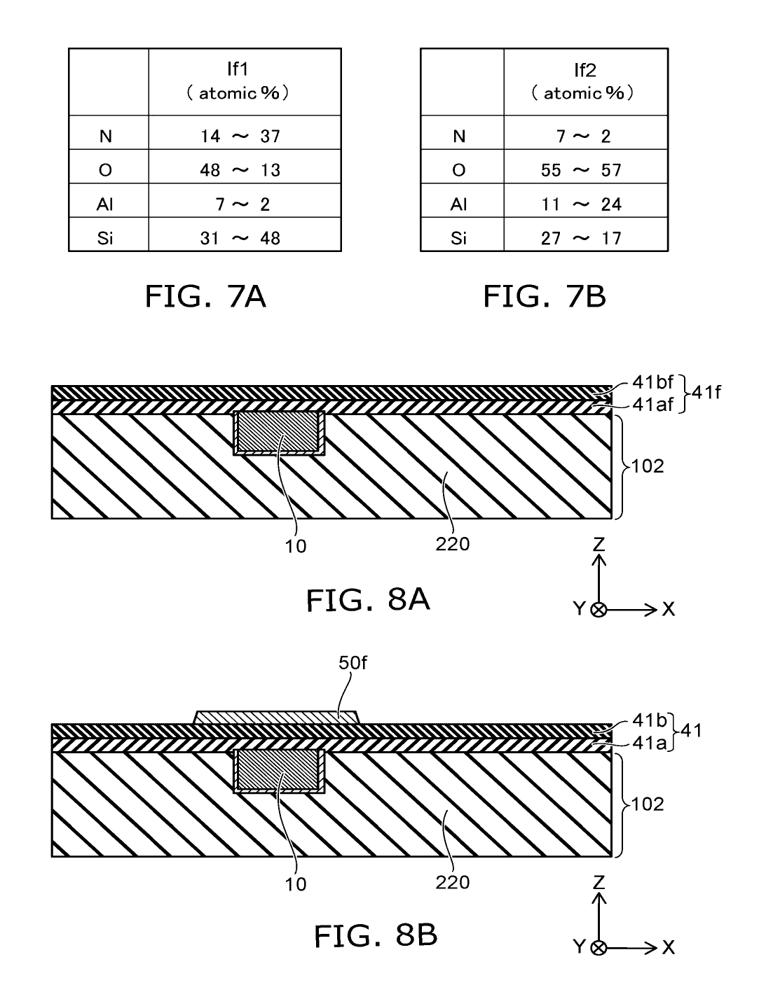

FIG. 7A and FIG. 7B are figures illustrating the composition ratios of the first layer If1 and the second layer If2.

FIG. 7A illustrates the composition ratios of nitrogen, oxygen, aluminum, and silicon of the first layer If1.

FIG. 7B illustrates the composition ratios of nitrogen, oxygen, aluminum, and silicon of the second layer If2.

The proportion (the composition ratio) of nitrogen N of the first layer If1 is larger than the proportion of nitrogen N of the second layer If2. For example, the composition ratio of nitrogen N of the first layer If1 is not less than 14 atomic % and not more than 37 atomic %; and the composition ratio of nitrogen N of the second layer If2 is not less than 2 atomic % and not more than 7 atomic %. The proportion of oxygen O of the first layer If1 is smaller than the proportion of oxygen O of the second layer If2. For example, the composition ratio of oxygen O of the first layer If1 is not less than 13 atomic % and not more than 48 atomic %; and the composition ratio of oxygen O of the second layer If2 is not less than 55 atomic % and not more than 57 atomic %. The proportion of aluminum Al of the first layer If1 is smaller than the proportion of aluminum Al of the second layer If2. For example, the composition ratio of aluminum Al of the first layer If1 is not less than 2 atomic % and not more than 7 atomic %. The composition ratio of aluminum Al of the second layer If2 is not less than 11 atomic % and not more than 24 atomic %. The proportion of silicon Si of the first layer If1 is larger than the proportion of silicon Si of the second layer If2. For example, the composition ratio of silicon Si of the first layer If1 is not less than 31 atomic % and not more than 48 atomic %; and the composition ratio of silicon Si of the second layer If2 is not less than 17 atomic % and not more than 27 atomic %.

In the description recited above, the semiconductor layer 50 that includes the oxide is covered with the first insulating portion 41 including silicon nitride/aluminum oxide and with the second insulating portion 42 including silicon nitride/aluminum oxide. Thereby, the penetration of the hydrogen into the semiconductor layer 50 can be suppressed. However, in such a case, there is a possibility that hydrogen may not be supplied to the substrate 103 used to form the foundation.

Heat treatment of the substrate 103 in a hydrogen-containing atmosphere is necessary for damage recovery of LSI (Large Scale Integration). Accordingly, it is favorable to be able to supply hydrogen to the substrate 103 while suppressing the penetration of the hydrogen into the semiconductor layer 50.

To this end, as shown in FIG. 1, the third insulating portion 43 includes a first region r1 and a second region r2. The first region r1 overlaps the semiconductor layer 50 in the Z-axis direction. The second region r2 is arranged with the first region r1 in the X-axis direction and does not overlap the semiconductor layer 50 in the Z-axis direction. A portion of the second region r2 does not overlap the first layer If1 and the second layer If2 in the Z-axis direction. More specifically, the portion of the second region r2 includes the trench portion 60 provided around the semiconductor layer 50. The trench portion 60 is formed by etching the second silicon nitride layer 42b, the second aluminum oxide layer 42a, and the first aluminum oxide layer 41b. The first silicon nitride layer 41a is exposed by providing the trench portion 60. The third insulating portion 43 is filled into the trench portion 60.

Thus, it is more favorable to provide the trench portion 60 around the semiconductor layer 50. Thereby, it is possible to supply the hydrogen to the substrate 103. That is, the supply of the hydrogen to the substrate 103 is possible while suppressing the penetration of the hydrogen into the semiconductor layer 50.

According to the embodiment, the penetration of the hydrogen into the semiconductor layer can be suppressed by providing the insulating layers including silicon nitride/aluminum oxide to cover the semiconductor layer including the oxide. Therefore, the resistance reduction of the semiconductor layer can be suppressed; and the stabilization of the electrical characteristics can be realized. Thereby, a semiconductor device that has stable electrical characteristics can be provided.

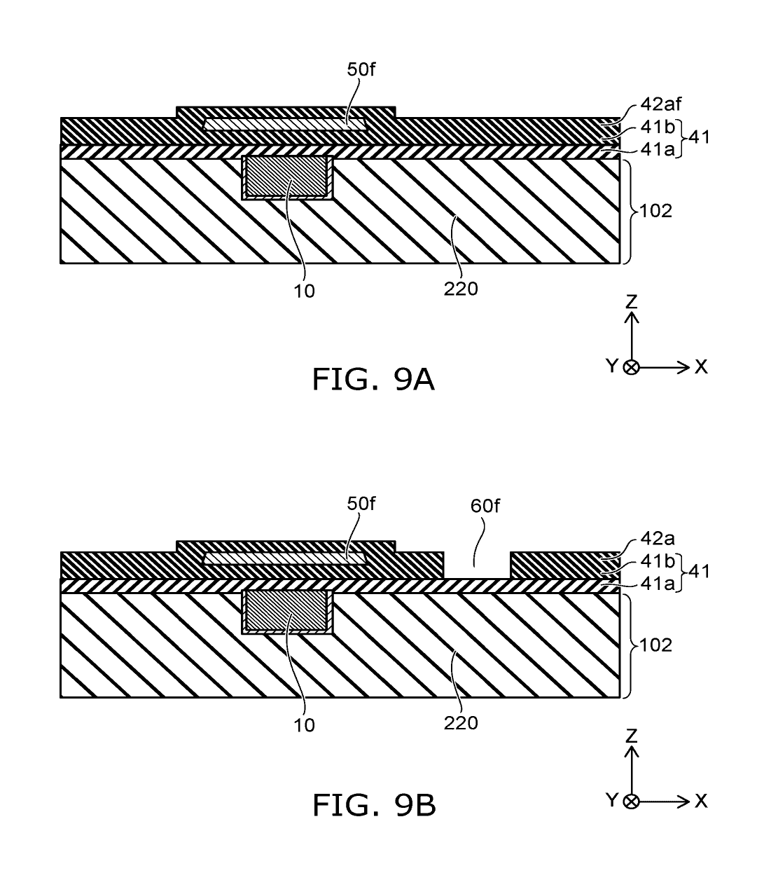

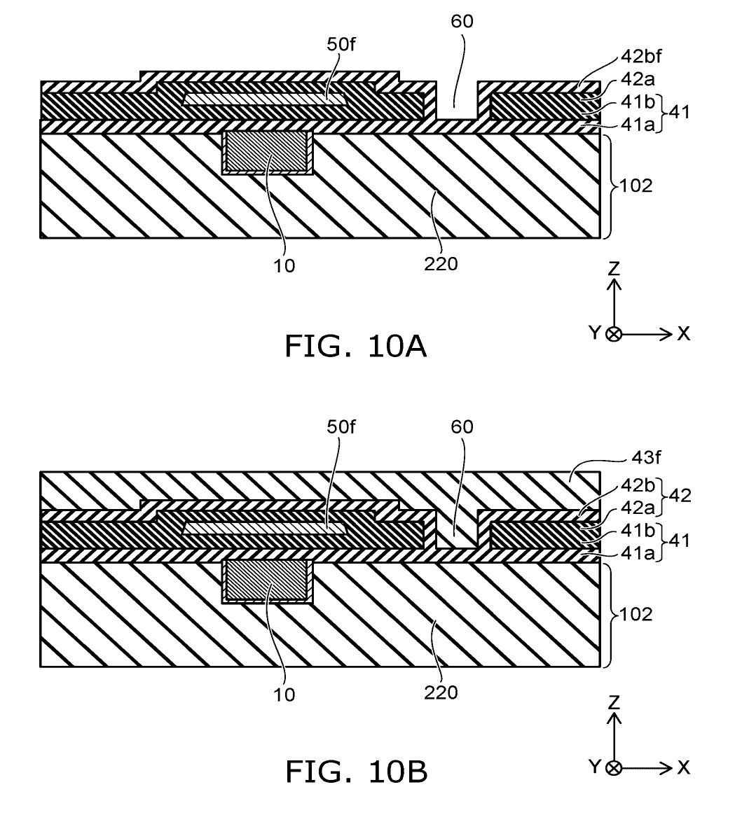

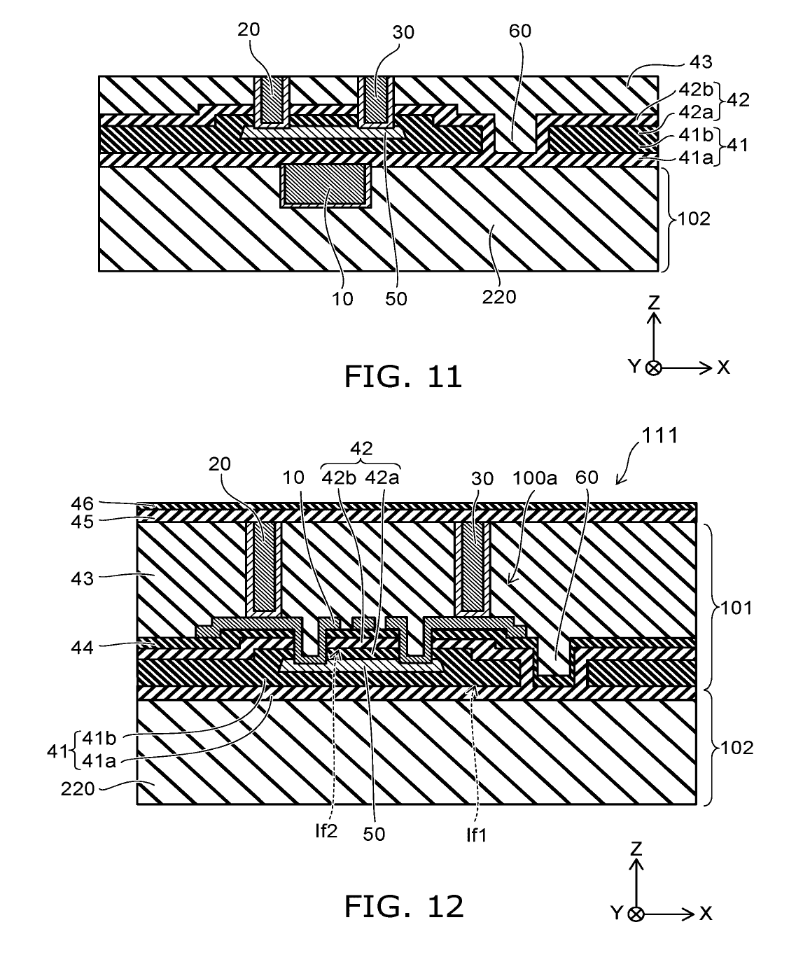

FIG. 8A, FIG. 8B, FIG. 9A, FIG. 9B, FIG. 10A, FIG. 10B, and FIG. 11 are schematic cross-sectional views in order of the processes, illustrating a method for manufacturing the semiconductor device according to the first embodiment.

As shown in FIG. 8A, a first insulating film 41f that is used to form the first insulating portion 41 is formed on the gate electrode 10 formed in the second interconnect layer 102. For example, DC magnetron sputtering is used to form a gate electrode film used to form the gate electrode 10. In such a case, the DC magnetron sputtering is implemented in an Ar atmosphere. The material of the gate electrode film in such a case is, for example, W, Mo, Ta, Ti, Al, AlNd, Cu, etc. DC reactive magnetron sputtering may be used to form the gate electrode film. In the case where TaN or TiN is used, the DC reactive magnetron sputtering is performed in an Ar/N₂ atmosphere. In the case where ITO or IZO is used, the DC reactive magnetron sputtering is performed in an Ar/O₂ atmosphere.

The gate electrode 10 is formed by patterning the gate electrode film. For example, the patterning includes reactive ion etching. In such a case, the material of the gate electrode film is, for example, W, Mo, Ta, Ti, Al, AlNd, etc. Acid-solution wet etching may be used to pattern the gate electrode 10. In such a case, the material of the gate electrode film is, for example, W, Mo, Ta, Ti, Al, AlNd, Cu, etc.

A first silicon nitride film 41af that is used to form the first silicon nitride layer 41a and a first aluminum oxide film 41bf that is used to form the first aluminum oxide layer 41b are formed as the first insulating film 41f on the gate electrode 10. PECVD (Plasma Enhanced Chemical Vapor Deposition) is used to form the first insulating film 41f. RF reactive magnetron sputtering may be used to form the first aluminum oxide film 41bf. In such a case, the RF reactive magnetron sputtering is implemented in an Ar/O₂ atmosphere. Anodic oxidation and/or ALD (Atomic Layer Deposition) may be used to form the first aluminum oxide film 41bf. Heat treatment of the first insulating film 41f may be implemented after forming the first insulating film 41f. For example, at least one of a clean oven or a quartz furnace is used in the heat treatment. In such a case, the heat treatment is performed in a N₂ atmosphere at a temperature of 200° C. to 600° C., and favorably at 350° C. to 500° C.

As shown in FIG. 8B, a semiconductor film 50f that is used to form the semiconductor layer 50 is formed on the first insulating portion 41. DC reactive magnetron sputtering is used to form the semiconductor film 50f. In such a case, the DC reactive magnetron sputtering is implemented in an Ar/O₂ atmosphere or in an Ar/O₂/N₂ atmosphere.

The semiconductor film 50f is patterned. For example, acid-solution wet etching is used to pattern the semiconductor film 50f. Reactive ion etching may be used to pattern the semiconductor film 50f. Heat treatment may be performed after patterning the semiconductor film 50f. For example, at least one of a clean oven or a quartz furnace is used in the heat treatment. In such a case, the heat treatment is performed in a N₂/O₂ atmosphere at a temperature of 200° C. to 600° C., and favorably at 300° C. to 500° C.

As shown in FIG. 9A, a second aluminum oxide film 42af that is used to form the second aluminum oxide layer 42a is formed on the semiconductor film 50f. RF reactive magnetron sputtering may be used to form the second aluminum oxide film 42af. In such a case, the RF reactive magnetron sputtering is implemented in an Ar/O₂ atmosphere. Anodic oxidation may be used to form the second aluminum oxide film 42af. Heat treatment may be performed after forming the second aluminum oxide film 42af. For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 300° C. to 500° C.

As shown in FIG. 9B, an opening 60f that is used to form the trench portion 60 is formed by performing dry etching of the second aluminum oxide layer 42a and the first aluminum oxide layer 41b around the semiconductor film 50f. Specifically, reactive ion etching (RIE) which is an example of dry etching is used. Ion milling may be used.

As shown in FIG. 10A, a second silicon nitride film 42bf that is used to form the second silicon nitride layer 42b is formed on the second aluminum oxide layer 42a. For example, PECVD is used to form the second silicon nitride film 42bf. RF reactive magnetron sputtering may be used to form the second silicon nitride film 42bf. In such a case, the RF reactive magnetron sputtering is implemented in an Ar/O₂ atmosphere. The second silicon nitride film 42bf is formed also on the side wall of the opening 60f and is used to form the trench portion 60. Heat treatment may be performed after forming the second silicon nitride film 42bf. For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 300° C. to 500° C.

As shown in FIG. 10B, a third insulating film 43f that is used to form the third insulating portion 43 is formed on the second silicon nitride layer 42b. The material of the third insulating film 43f includes, for example, silicon oxide, silicon oxynitride, etc. For example, PECVD is used to form the third insulating film 43f. RF reactive magnetron sputtering may be used to form the third insulating film 43f. In such a case, the RF reactive magnetron sputtering is implemented in an Ar/O₂ atmosphere. Heat treatment may be performed after forming the third insulating film 43f. For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 300° C. to 500° C.

As shown in FIG. 11, the source electrode 20 and the drain electrode 30 are formed in openings formed in the third insulating portion 43 and the second insulating portion 42. The openings that reach the semiconductor film 50f are formed in the third insulating portion 43 and the second insulating portion 42 by dry etching. Specifically, RIE which is an example of dry etching can be used.

Recesses are formed by removing a portion of the semiconductor film 50f. Thereby, the semiconductor layer 50 is formed. The portion of the semiconductor film 50f is removed by wet etching. Specifically, acid-solution wet etching which is an example of wet etching is used.

A conductive film that is used to form the source electrode 20 and the drain electrode 30 is formed. For example, the conductive film is filled into the recesses formed as recited above. For example, DC magnetron sputtering can be used to form the conductive films. In such a case, the DC magnetron sputtering is implemented in an Ar atmosphere. The material of the conductive film is, for example, Ti, Mo, Al, Cu, Ta, or W. DC reactive magnetron sputtering may be used to form the conductive film. In such a case, the DC reactive magnetron sputtering is implemented in an Ar/N₂ atmosphere. The material of the conductive film may be, for example, TiN, TaN, or MoN. In the case where ITO, IZO, or InGaZnO is used, the DC reactive magnetron sputtering is performed in an Ar/O₂ atmosphere. In the case where InGaZnO:N is used, the DC reactive magnetron sputtering is performed in an Ar/O₂/N₂ atmosphere.

The source electrode 20 and the drain electrode 30 are formed by patterning the conductive film. The patterning includes reactive ion etching. The patterning may include acid-solution wet etching. Thereby, the semiconductor layer 50 and the source electrode 20 are connected; and the semiconductor layer 50 and the drain electrode 30 are connected. Heat treatment may be implemented after the patterning. For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 250° C. to 350° C.

An example of a semiconductor device including a thin film transistor having a bottom-gate structure is described in the embodiment.

According to the embodiment, the penetration of the hydrogen into the semiconductor layer can be suppressed by providing the insulating layers including silicon nitride/aluminum oxide to cover the semiconductor layer including the oxide in the semiconductor device having the bottom-gate structure. Therefore, the resistance reduction of the semiconductor layer can be suppressed; and the stabilization of the electrical characteristics can be realized. Thereby, a semiconductor device that has stable electrical characteristics can be provided.

### Second Embodiment

FIG. 12 is a schematic cross-sectional view illustrating a semiconductor device according to a second embodiment.

In the semiconductor device 111 according to the embodiment, the arrangement of the gate electrode 10 is different from the arrangement of the gate electrode 10 of the semiconductor device 110 described in the first embodiment. Otherwise, the basic structure is similar.

The semiconductor device 111 includes the first interconnect layer 101 and the second interconnect layer 102. The first interconnect layer 101 is provided on the second interconnect layer 102. The substrate is not shown in the example.

The insulating layer 220 is provided in the second interconnect layer 102. The insulating layer 220 includes, for example, silicon oxide (SiOₓ).

The first interconnect layer 101 is provided on the second interconnect layer 102. A thin film transistor 100a is provided in the first interconnect layer 101. The thin film transistor 100a includes the gate electrode 10, the source electrode 20, the drain electrode 30, the first insulating portion 41, the second insulating portion 42, and the semiconductor layer 50.

The semiconductor device 111 further includes a fourth insulating portion 44, a fifth insulating portion 45, and a sixth insulating portion 46. The fourth insulating portion 44 is provided on the second insulating portion 42. The fourth insulating portion 44 includes, for example, aluminum oxide. In the example, the gate electrode 10 is provided on the semiconductor layer 50 with the fourth insulating portion 44 interposed. The third insulating portion 43 is provided on the gate electrode 10.

The fifth insulating portion 45 is provided on the third insulating portion 43. The fifth insulating portion 45 includes, for example, silicon nitride. The sixth insulating portion 46 is provided on the fifth insulating portion 45. The sixth insulating portion 46 includes, for example, aluminum oxide.

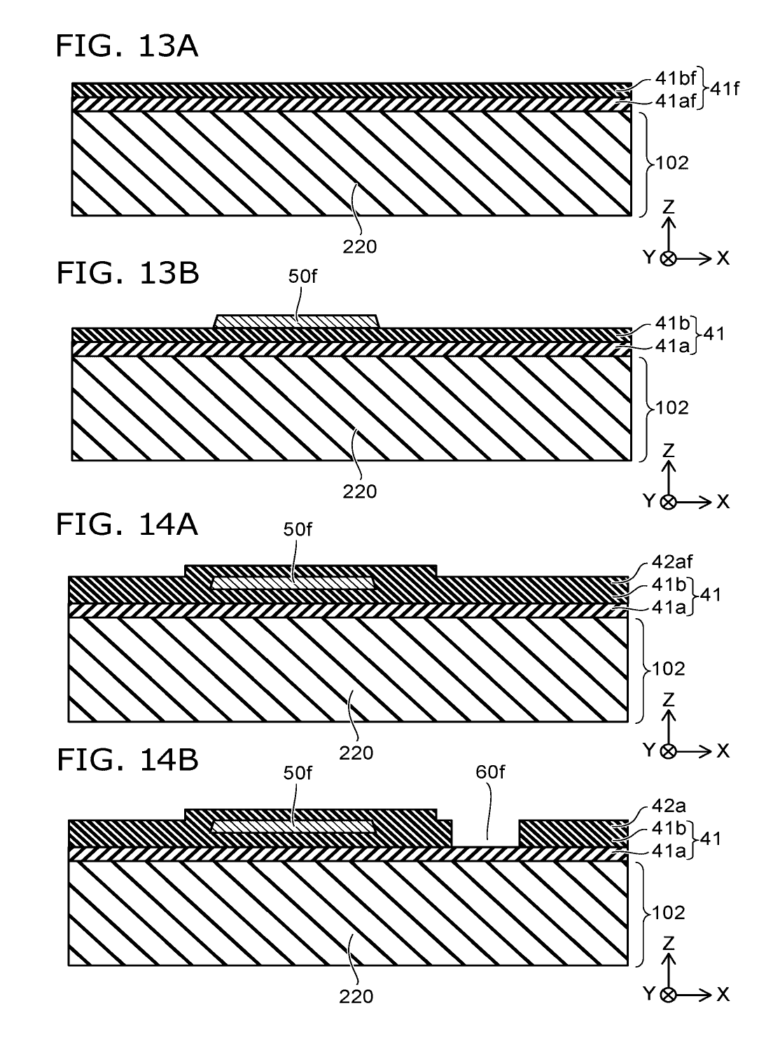

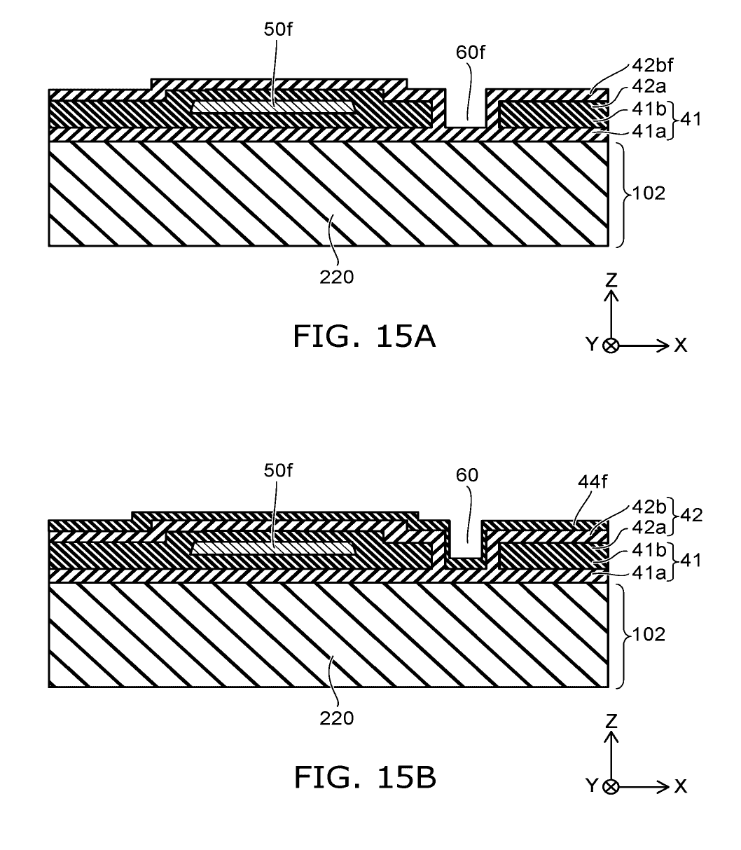

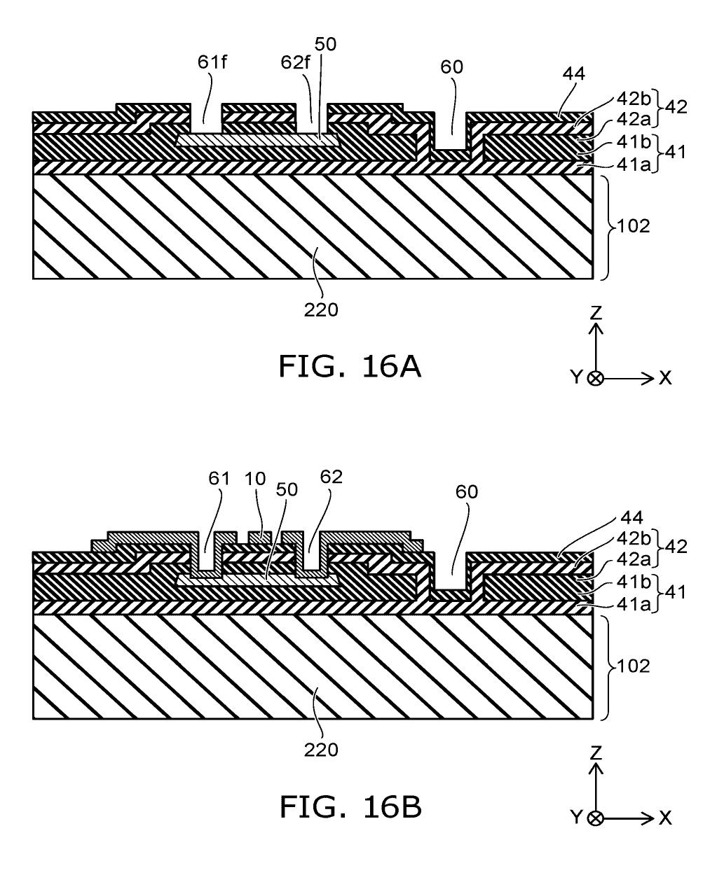

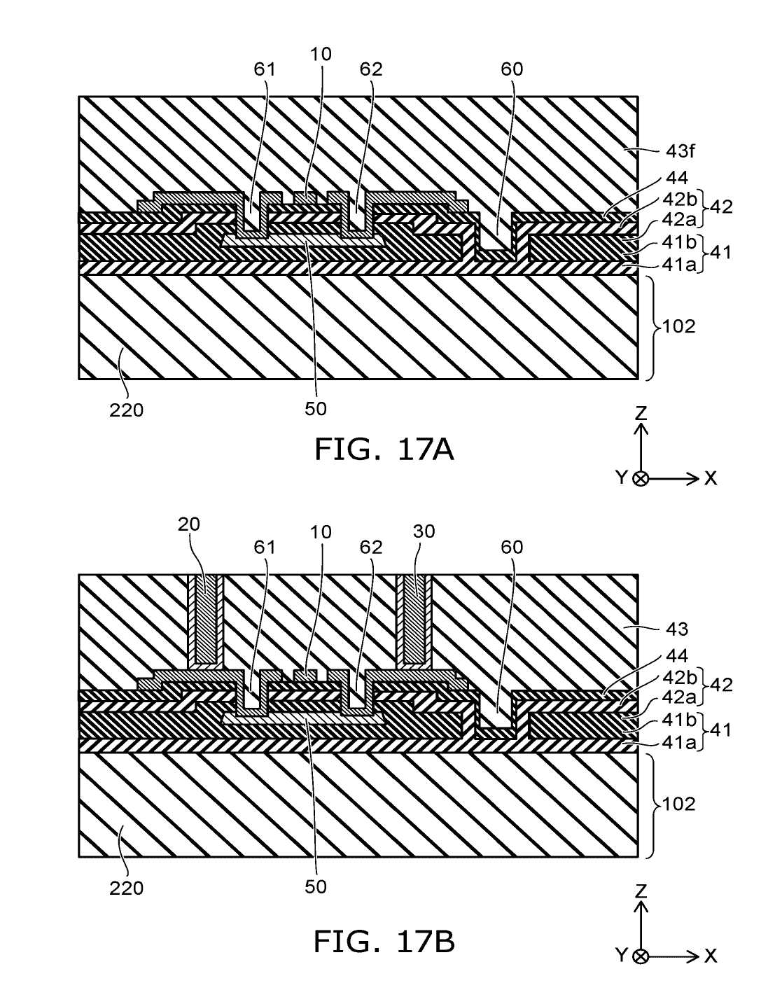

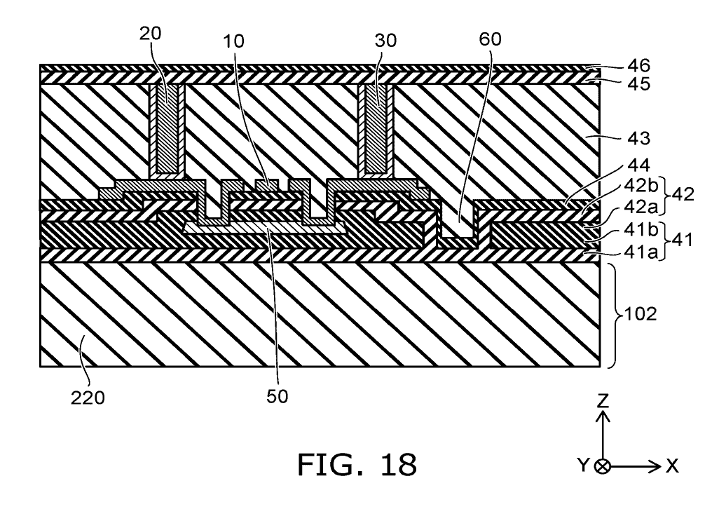

FIG. 13A, FIG. 13B, FIG. 14A, FIG. 14B, FIG. 15A, FIG. 15B, FIG. 16A, FIG. 16B, FIG. 17A, FIG. 17B, and FIG. 18 are schematic cross-sectional views in order of the processes, illustrating a method for manufacturing the semiconductor device according to the second embodiment.

As shown in FIG. 13A, the first silicon nitride film 41af that is used to form the first silicon nitride layer 41a and the first aluminum oxide film 41bf that is used to form the first aluminum oxide layer 41b are formed as the first insulating film 41f used to form the first insulating portion 41 on the second interconnect layer 102. PECVD is used to form the first insulating film 41f. RF reactive magnetron sputtering may be used to form the first aluminum oxide film 41bf. Anodic oxidation and/or ALD may be used to form the first aluminum oxide film 41bf. Heat treatment may be implemented after forming the first insulating film 41f. For example, at least one of a clean oven or a quartz furnace is used in the heat treatment.

As shown in FIG. 13B, the semiconductor film 50f that is used to form the semiconductor layer 50 is formed on the first insulating portion 41. DC reactive magnetron sputtering is used to form the semiconductor film 50f.

The semiconductor film 50f is patterned. For example, acid-solution wet etching is used to pattern the semiconductor film 50f. Reactive ion etching may be used to pattern the semiconductor film 50f. Heat treatment may be performed after patterning the semiconductor film 50f. For example, at least one of a clean oven or a quartz furnace is used in the heat treatment.

As shown in FIG. 14A, the second aluminum oxide film 42af that is used to form the second aluminum oxide layer 42a is formed on the semiconductor film 50f. RF reactive magnetron sputtering may be used to form the second aluminum oxide film 42af. Anodic oxidation and/or ALD may be used to form the second aluminum oxide film 42af. Heat treatment may be performed after forming the second aluminum oxide film 42af. For example, at least one of a clean oven or a quartz furnace is used in the heat treatment.

As shown in FIG. 14B, the opening 60f that is used to form the trench portion 60 is formed by performing dry etching of the second aluminum oxide layer 42a and the first aluminum oxide layer 41b around the semiconductor film 50f. Specifically, reactive ion etching which is an example of dry etching is used. Ion milling may be used.

As shown in FIG. 15A, the second silicon nitride film 42bf that is used to form the second silicon nitride layer 42b is formed on the second aluminum oxide layer 42a. For example, PECVD is used to form the second silicon nitride film 42bf. RF reactive magnetron sputtering may be used to form the second silicon nitride film 42bf. The second silicon nitride film 42bf is formed also on the side wall of the opening 60f. Heat treatment may be performed after forming the second silicon nitride film 42bf. For example, at least one of a clean oven or a quartz furnace is used in the heat treatment.

As shown in FIG. 15B, a fourth insulating film 44f that is used to form the fourth insulating portion 44 is formed on the second silicon nitride layer 42b. The material of the fourth insulating film 44f includes, for example, aluminum oxide. RF reactive magnetron sputtering may be used to form the fourth insulating film 44f. The fourth insulating film 44f is formed to cover the second silicon nitride layer 42b formed on the side wall of the opening 60f and is used to form the trench portion 60. Heat treatment may be performed after forming the fourth insulating film 44f. For example, at least one of a clean oven or a quartz furnace is used in the heat treatment.

As shown in FIG. 16A, openings 61f and 62f are formed in a portion of the semiconductor film 50f by performing dry etching of the fourth insulating portion 44, the second silicon nitride layer 42b, and the second aluminum oxide layer 42a. Specifically, reactive ion etching which is an example of dry etching is used. Further, recesses are formed by removing the portion of the semiconductor film 50f. Thereby, the semiconductor layer 50 is formed. The portion of the semiconductor film 50f is removed by wet etching. Specifically, acid-solution wet etching which is an example of wet etching is used.

As shown in FIG. 16B, the gate electrode 10 is formed on the fourth insulating portion 44 formed on the semiconductor layer 50. The gate electrode 10 is formed also on the side walls of the openings 61f and 62f and is used to form the recesses 61 and 62.

As shown in FIG. 17A, the third insulating film 43f that is used to form the third insulating portion 43 is formed on the first gate electrode 10 and the fourth insulating portion 44. The material of the third insulating film 43f includes, for example, silicon oxide, silicon oxynitride, etc. For example, PECVD is used to form the third insulating film 43f. RF reactive magnetron sputtering may be used to form the third insulating film 43f. Heat treatment may be performed after forming the third insulating film 43f. For example, at least one of a clean oven or a quartz furnace is used in the heat treatment.

As shown in FIG. 17B, the source electrode 20 and the drain electrode 30 are formed in openings formed in the third insulating portion 43. Openings that reach the gate electrode 10 are formed in the third insulating portion 43 by dry etching. Specifically, RIE which is an example of dry etching can be used. Ion milling may be used.

As shown in FIG. 18, the fifth insulating portion 45 is formed on the third insulating portion 43 in which the source electrode 20 and the drain electrode 30 are formed. Further, the sixth insulating portion 46 is formed on the fifth insulating portion 45. The material of the fifth insulating portion 45 includes, for example, silicon nitride. The material of the sixth insulating portion 46 includes, for example, aluminum oxide.

An example of a semiconductor device including a thin film transistor having a top-gate structure is described in the embodiment.

According to the embodiment, in the semiconductor device having the top-gate structure as well, the penetration of the hydrogen into the semiconductor layer can be suppressed by providing the insulating layers including silicon nitride/aluminum oxide to cover the semiconductor layer including the oxide. Therefore, the resistance reduction of the semiconductor layer can be suppressed; and the stabilization of the electrical characteristics can be realized. Thereby, a semiconductor device that has stable electrical characteristics can be provided.

According to the embodiments, a semiconductor device having stable electrical characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components such as substrates, memory strings, semiconductor layers, source electrodes, drain electrodes, first insulating portions, second insulating portions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a substrate;
a semiconductor layer including an oxide and being separated from the substrate in a first direction;
a source electrode electrically connected to the semiconductor layer;
a drain electrode electrically connected to the semiconductor layer and arranged with the source electrode in a second direction crossing the first direction;
a first insulating portion provided between the substrate and the semiconductor layer; and
a second insulating portion, the semiconductor layer being provided between the first insulating portion and the second insulating portion,
the first insulating portion including a first silicon nitride layer, and a first aluminum oxide layer stacked with the first silicon nitride layer,
the second insulating portion including a second aluminum oxide layer, and a second silicon nitride layer stacked with the second aluminum oxide layer.

2. The device according to claim 1, wherein
the first insulating portion includes a first layer positioned between the first silicon nitride layer and the first aluminum oxide layer, and
the second insulating portion includes a second layer positioned between the second aluminum oxide layer and the second silicon nitride layer.

3. The device according to claim 2, wherein
a proportion of nitrogen of the first layer is larger than a proportion of nitrogen of the second layer,
a proportion of oxygen of the first layer is smaller than a proportion of oxygen of the second layer,
a proportion of aluminum of the first layer is smaller than a proportion of aluminum of the second layer, and
a proportion of silicon of the first layer is larger than a proportion of silicon of the second layer.

4. The device according to claim 2, further comprising a third insulating portion provided on the second insulating portion,
the third insulating portion including:
a first region overlapping the semiconductor layer in the first direction; and
a second region being arranged with the first region in the second direction and not overlapping the semiconductor layer in the first direction,
a portion of the second region not overlapping the first layer and the second layer in the first direction.

5. The device according to claim 4, wherein the portion of the second region includes a trench portion provided around the semiconductor layer.

6. The device according to claim 4, wherein the third insulating portion includes one of silicon oxide or silicon oxynitride.

7. The device according to claim 1, wherein
the first aluminum oxide layer is provided between the first silicon nitride layer and the semiconductor layer, and
the second aluminum oxide layer is provided between the second silicon nitride layer and the semiconductor layer.

8. The device according to claim 1, wherein
a thickness of the first silicon nitride layer is not less than 10 nanometers and not more than 100 nanometers,
a thickness of the first aluminum oxide layer is not less than 5 nanometers and not more than 100 nanometers,
a thickness of the second aluminum oxide layer is not less than 5 nanometers and not more than 100 nanometers, and
a thickness of the second silicon nitride layer is not less than 10 nanometers and not more than 100 nanometers.

9. The device according to claim 1, further comprising a gate electrode,
the first insulating portion being provided between the semiconductor layer and the gate electrode, the semiconductor layer including an oxide of at least one of indium, gallium, or zinc.

10. The device according to claim 1, further comprising a gate electrode,
the second insulating portion being provided between the semiconductor layer and the gate electrode, the semiconductor layer including an oxide of at least one of indium, gallium, or zinc.
